(19) United States
(12) Patent Application Publication
(10) Pub. No.: US 2021/0217982 A1
(43) Pub. Date: Jul. 15, 2021

(54) DISPLAY PANEL AND DISPLAY PANEL MANUFACTURING METHOD

(71) Applicant: WUHAN CHINA STAR OPTOELECTRONICS SEMICONDUCTOR DISPLAY TECHNOLOGY CO., LTD., Wuhan, Hubei (CN)

(72) Inventor: Bo WANG, Wuhan, Hubei (CN)

(21) Appl. No.: 16/086,441

(22) PCT Filed: Aug. 30, 2018
(86) PCT No.: PCT/CN2018/103324

§ 371 Date: Sep. 19, 2018

(30) Foreign Application Priority Data
May 21, 2018 (CN) 201810486221.2

(51) Int. Cl. H01L 51/50; H01L 51/56; H01L 51/00

(52) U.S. Cl. CPC H01L 51/5088; H01L 51/56; H01L 51/0026; H01L 2251/558; H01L 51/0037

(57) ABSTRACT

A display panel and a display panel manufacturing method are provided. The display panel includes a substrate, an anode layer, an OLED layer and a cathode layer. The OLED layer includes a first common layer, a light-emitting layer and a second common layer that a sequentially stacked over one another. The present invention, by doping metal oxide in the hole injection layer of the OLED layer, lowers the injection energy barrier between the anode and the hole injection layer, increases hole injection capability. That is, current density and luminous intensity of OLED devices are increased.

### FIELD OF INVENTION

The present invention relates to liquid crystal display fields, especially to a display panel and a display panel manufacturing method.

### BACKGROUND OF INVENTION

A conventional OLED display panel primarily includes a substrate, an anode, a hole injection layer, a hole transport layer, a light-emitting layer, an electron transport layer, an electron injection layer and a cathode. The light-emitting principle of the OLED display panel is that under the effect of an applied electric field, electrons are injected from the cathode to a lowest unoccupied molecular orbital (LUMO) of the organic matter, and holes are injected from the anode to a highest occupied orbital of the organic material (HOMO). The electrons and the holes encounter one another on the light-emitting layer, compound and form excitons. The excitons migrate under effect of the electric field and transfer energy to the luminescent material. The excited electrons transition from the ground state to the excited state. The excited state energy is deactivated by radiation, generates photons, and releases light energy.

Furthermore, during operation of the OLED display panel, the level of the energy barrier between the organic material and the electrode determines the number of injected holes and electrons, which affects current density, brightness, and luminous efficiency of the OLED display panel. In the current OLED display panel, energy barrier of the interface between the anode and the hole injection layer is too high and the hole injection capability is limited, which becomes a bottleneck restricting performance of the OLED display panel.

### SUMMARY OF INVENTION

The present invention provides a display panel and a display panel manufacturing method to solve the issue that in a conventional organic light-emitting diode (OLED) display panel, an energy barrier of the interface between an anode and a hole injection layer is excessive high.

To solve the above issue, the present invention provides a technical solution as follows.

The present invention provides a display panel, and the display panel includes:

a substrate;

an anode layer formed on the substrate;

an OLED layer formed on the anode layer, the OLED layer including a first common layer, a light-emitting layer and a second common layer that are sequentially stacked over one another, wherein the first common layer comprises particles made of metal oxide;

a cathode layer formed on the OLED layer.

In the display panel of the present invention, the metal oxide is one of ruthenium(IV) oxide, molybdenum oxide, vanadium oxide and tungsten oxide or a combination of at least two of ruthenium(IV) oxide, molybdenum oxide, vanadium oxide and tungsten oxide.

In the display panel of the present invention, the first common layer includes a polymer compound, and the polymer compound one of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK) or a combination of at least two of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK).

In the display panel of the present invention, the first common layer includes a hole injection layer and a hole transport layer the first common layer configured for hole injection and transport; and

The second common layer comprises an electron injection layer and an electron transport layer the second common layer configured for electron injection and transport.

In the display panel of the present invention, the hole injection layer includes particles made of metal oxide.

In the display panel of the present invention, a thickness of the hole injection layer is 10-50 nm.

The present invention provides a display panel manufacturing method, wherein a display panel includes a substrate, an anode layer, an OLED layer and a cathode layer, the OLED layer comprises a hole injection layer, a hole transport layer light-emitting layer, an electron injection layer and an electron transport layer that are sequentially stacked over one another;

the display panel manufacturing method comprises steps as follows:

preparing a polymer compound solution of the hole injection layer;

mixing particles made of metal oxide with the polymer compound solution to form a mixing solution A;

coating the mixing solution A on the anode layer to form a hole injection layer film; and

processing the hole injection layer film at a predetermined temperature by an annealing process.

In the display panel of the present invention, the metal oxide is one of ruthenium(IV) oxide, molybdenum oxide, vanadium oxide and tungsten oxide or a combination of at least two of ruthenium(IV) oxide, molybdenum oxide, vanadium oxide and tungsten oxide.

In the display panel of the present invention, the polymer compound one of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK) or a combination of at least two of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole).

In the display panel of the present invention, the predetermined temperature of the annealing process is 120° C.

The present invention also provides a display panel including:

a substrate;

an anode layer formed on the substrate;

an OLED layer formed on the anode layer, and the OLED layer comprising a first common layer, a light-emitting layer and a second common layer sequentially stacked over one another, wherein the first common layer comprises particles made of metal oxide; and

a cathode layer formed on the OLED layer.

In the display panel of the present invention, the first common layer includes a polymer compound, and the polymer compound is one of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK) or a combination of at least two of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK).

In the display panel of the present invention, the first common layer includes a hole injection layer and a hole transport layer, and the first common layer is configured for hole injection and transport; and

The second common layer comprises an electron injection layer and an electron transport layer, and the second common layer is configured for electron injection and transport.

In the display panel of the present invention, the hole injection layer includes particles made of metal oxide.

In the display panel of the present invention, a thickness of the hole injection layer is 10-50 nm.

Advantages: the present invention, by doping metal oxide in the hole injection layer of the OLED layer, lowers the injection energy barrier between the anode and the hole injection layer, increases hole injection capability, that is, current density and luminous intensity of OLED devices are increased while the production cost of OLED panels is reduced.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic view of a film structure of a first embodiment of a display panel of the present invention;

FIG. 2 is a curve chart of current densities of the first embodiment of present invention and a conventional hole injection layer;

FIG. 3 is a curve chart of luminous intensities of the first embodiment of the present invention and a conventional hole injection layer;

FIG. 4 a schematic view of a film structure of a second embodiment of the display panel of the present invention; and

FIG. 5 is a flowchart of a display panel manufacturing method of the present invention.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface” and etc., only refer to the directions of the appended figures. Therefore, the terminologies of direction are used for explanation and comprehension of the present invention, instead of limiting the present invention. In the figures, units with similar structures are marked with the same reference numerals.

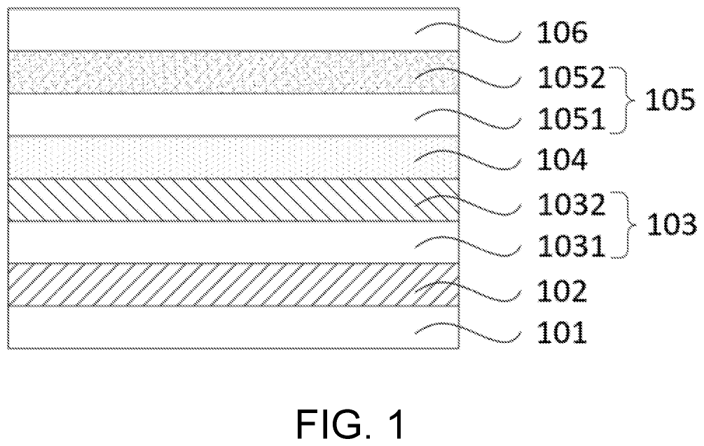

FIG. 1 is a schematic view of a film structure of a first embodiment of a display panel of the present invention. The display panel includes a substrate 101, an anode layer 102, an OLED layer and a cathode layer 106.

Raw material of the substrate 101 may be one of a glass substrate, a quartz substrate and a resin substrate.

The anode layer 102 is formed on the substrate 101, and the anode layer 102 includes at least two anodes arranged in an array. The anode layer 102 is mainly configured to absorb holes of electrons.

The OLED layer is formed on the anode layer 102. Adjacent OLED layers are separated by a pixel definition layer (not shown). the OLED layer includes a first common layer 103, a light-emitting layer 104, and a second common layer 105 that are sequentially stacked over one another.

The first common layer 103 is configured for hole injection and transport. The first common layer 103 includes a hole injection layer 1031 and a hole transport layer 1032. Therefore, the first common layer 103 can be called hole transport function layer. The second common layer 105 is formed on the first common layer 103. The first common layer 103 is configured for hole injection and transport. The second common layer 105 includes an electron injection layer 1052 and an electron transport layer 1051. Therefore, the second common layer 105 can be called the electron transport function layer.

The light-emitting layer 104 is formed between the first common layer 103 and the second common layer 105. The light-emitting layer 104 is an organic semiconductor, has a special energy band structure, and is able to emit photons with a specific wavelength after absorbing the electrons mitigated from the anode. Such photons enter our eyes and change to colors that we see.

Furthermore, the first common layer 103 includes particles made of metal oxide. Preferably, the particles are located in the hole injection layer 1031 of the first common layer 10. The metal oxide can be one of ruthenium(IV) oxide, molybdenum oxide, vanadium oxide and tungsten oxide or a combination of at least two of ruthenium(IV) oxide, molybdenum oxide, vanadium oxide and tungsten oxide.

In the present embodiment, the particles are mainly doped with the polymer compound in the hole injection layer 1031 to form a mixing hole injection layer (i.e. hole injection layer 1031). Preferably, the polymer compound is one of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK) or a combination of at least two of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK).

It can be understood that in the present invention, particles made of metal oxide are nano particles, and a thickness of the mixing hole injection layer is preferably 10-50 nm.

In the present embodiment, the present invention employs the metal oxide being molybdenum oxide and the polymer compound of the hole injection layer being Poly(3,4-ethylenedioxythiophene) (PEDOT) for explanation.

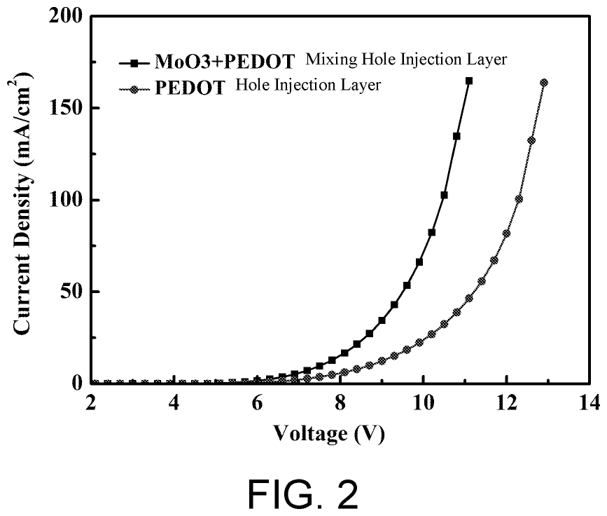

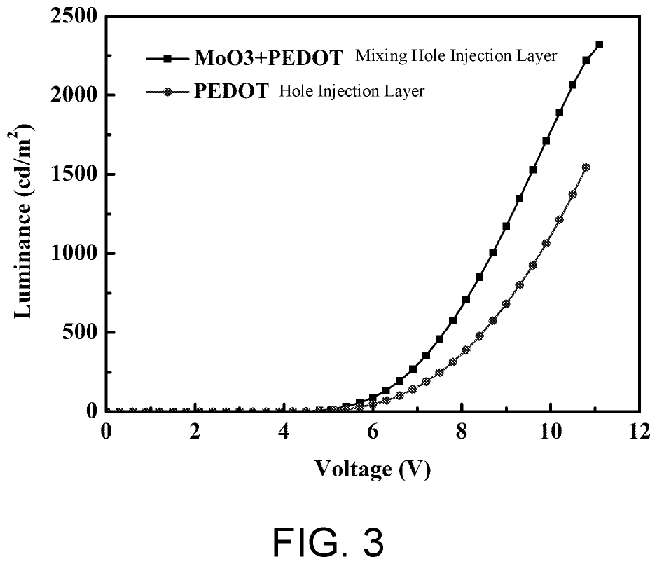

With reference FIGS. 2 and 3, when the molybdenum oxide particles are doped in the hole injection layer, under the same applied voltage, current density and luminous intensity of the hole injection layer doped with molybdenum oxide are greater than the hole injection layer without molybdenum oxide, lower the injection energy barrier between the anode and the hole injection layer, increase hole injection capability, and enhance current density and luminous of the OLED device.

The cathode layer 106 is formed on the OLED layer, and the cathode layer 106 is configured to provide electrons.

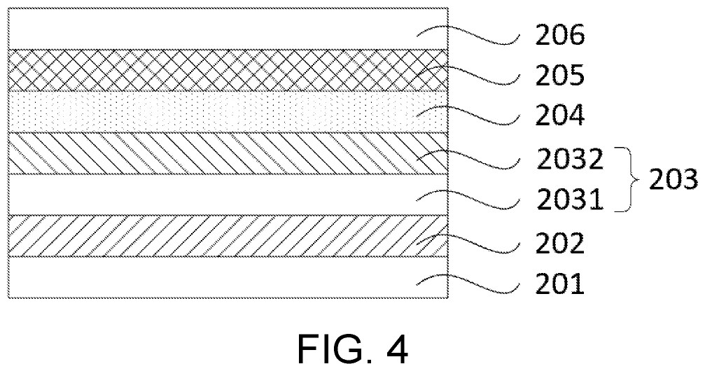

It may be understood that the hole injection layer 1031 in the present invention can be used in fields of quantum dot light-emitting diodes (QLEDs), Perovskite LEDs, solar batteries, organic film transistors. FIG. 4 shows a film structure of a QLED device.

In the present embodiment, the electron injection layer and the electron transport layer are replaced with merely with a single second common layer 205. Preferably, raw material of the second common layer 205 is zinc oxide, and rest of structures are the same as the structures shown in FIG. 1, and are not described in details here.

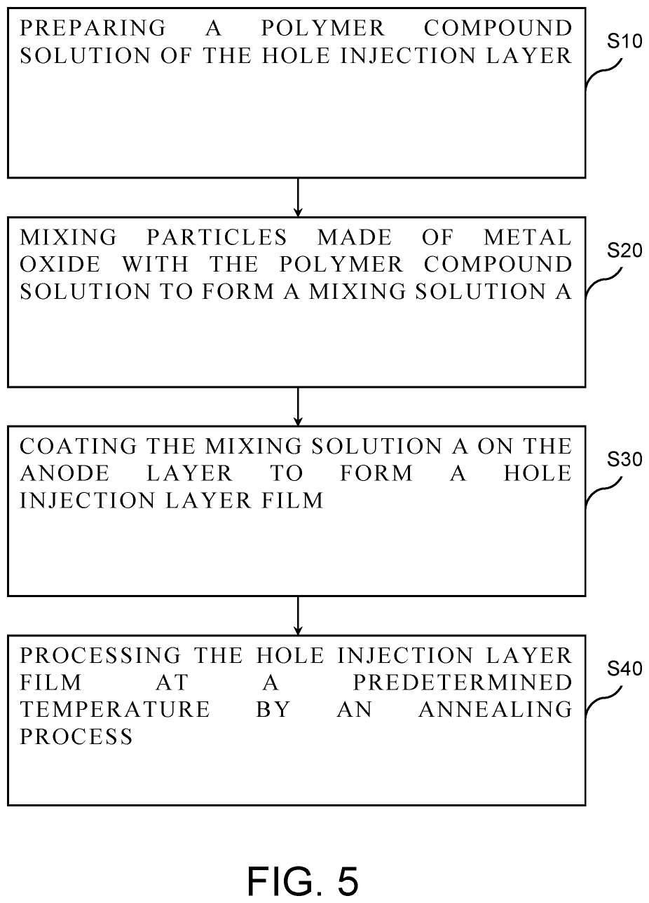

With reference to FIG. 5 that is a flow chart of a display panel manufacturing method of the present invention. The display panel includes a substrate, an anode layer, an OLED layer and a cathode layer, the OLED layer includes a hole injection layer, a hole transport layer, a light-emitting layer, an electron injection layer and an electron transport layer that are sequentially stacked over one another.

The manufacturing method includes:

Step S10, including preparing a polymer compound solution of the hole injection layer;

In the present step, raw material solution is disposed and formed on the hole injection layer; wherein, the polymer compound is one of Poly(3,4-ethylenedioxythiophene) (PEDOT), Poly[N,N′-bis(4-butylphenyl)-N,N′-bisphenylbenzidine] (Poly-TPD), Poly(9-vinylcarbazole) (PVK) or a combination of at least one of Poly(3,4-ethylenedioxythiophene) (PEDOT), Poly[N,N′-bis(4-butylphenyl)-N,N′-bisphenylbenzidine] (Poly-TPD), Poly(9-vinylcarbazole) (PVK).

Step S20, including mixing particles made of metal oxide with the polymer compound solution to form a mixing solution A;

In the present step, the particles made of metal oxide are mixed with the polymer compound solution to form the mixing solution A. The mixing solution is particles suspension. The metal oxide can be one of ruthenium(IV) oxide, molybdenum oxide, vanadium oxide, tungsten oxide or a combination of at least two of ruthenium(IV) oxide, molybdenum oxide, vanadium oxide, tungsten oxide.

Step S30, including coating the mixing solution A on the anode layer to form a hole injection layer film;

The present step evenly coats the blended mixing solution A on the anode layer to form the mixing hole injection layer. A coating method for the present step is spin coating method that forms the evenly mixing hole injection layer on the anode layer. Preferably, a thickness of the mixing hole injection layer is 10-50 nm.

Step S40, including processing the hole injection layer film at a predetermined temperature by an annealing process.

The present step disposes the prepared hole injection layer in a vacuum drying oven to proceed with the annealing process. Preferably, the temperature of the vacuum drying oven is 120° C., and the annealing processing time is 30-60 min.

Preferably, in the present invention, the light-emitting layer, the electron injection layer, and the electron transport layer and cathode layer over the mixing hole injection layer can all be prepared by a vacuum evaporation apparatus.

FIGS. 2 and 3 show comparison curve charts of current densities and luminous intensities of the hole injection layer doped with molybdenum oxide and the hole injection layer without molybdenum oxide. Under the same applied voltage, current density and luminous intensity of the hole injection layer doped with molybdenum oxide are greater than the hole injection layer without molybdenum oxide, lower the injection energy barrier between the anode and the hole injection layer, increase hole injection capability, and enhance current density and luminous of the OLED device.

The present invention provides a display panel and a display panel manufacturing method. The display panel includes a substrate, an anode layer, an OLED layer and a cathode layer, the OLED layer includes a first common layer, a light-emitting layer and a second common layer that are sequentially stacked over one another. The present invention, by doping metal oxide in the hole injection layer of the OLED layer, lowers the injection energy barrier between the anode and the hole injection layer, increases hole injection capability, that is, current density and luminous intensity of OLED devices are increased while the production cost of OLED panels is reduced.

Although the preferred embodiments of the present invention have been disclosed as above, the aforementioned preferred embodiments are not used to limit the present invention. The person of ordinary skill in the art may make various of changes and modifications without departing from the spirit and scope of the present invention. Therefore, the scope of protection of the present invention is defined by the scope of the claims.

What is claimed is:

1. A display panel, comprising:
a substrate;
an anode layer formed on the substrate;
an organic light-emitting diode (OLED) layer formed on the anode layer, and the OLED layer comprising a first common layer, a light-emitting layer and a second common layer that are sequentially stacked over one another, wherein the first common layer comprises particles made of metal oxide, and the metal oxide is one of ruthenium(IV) oxide, molybdenum oxide, vanadium oxide and tungsten oxide or a combination of at least two of ruthenium(IV) oxide, molybdenum oxide, vanadium oxide and tungsten oxide; and
a cathode layer formed on the OLED layer.

2. The display panel as claimed in claim 1, wherein the first common layer comprises a polymer compound, and the polymer compound is one of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK) or a combination of at least two of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK).

3. The display panel, as claimed in claim 1, wherein the first common layer comprises a hole injection layer and a hole transport layer the first common layer configured for hole injection and transport; and
the second common layer comprises an electron injection layer and an electron transport layer the second common layer configured for electron injection and transport.

4. The display panel as claimed in claim 3, wherein the hole injection layer comprises particles made of metal oxide.

5. The display panel as claimed in claim 3, wherein a thickness of the hole injection layer is 10-50 nm.

6. A display panel manufacturing method, wherein a display panel comprises a substrate, an anode layer, an organic light-emitting diode (OLED) layer and a cathode layer, the OLED layer comprises a hole injection layer, a hole transport layer light-emitting layer, an electron injection layer and an electron transport layer that are sequentially stacked over one another;
the display panel manufacturing method comprises steps as follows:
preparing a polymer compound solution of the hole injection layer;
mixing particles made of metal oxide with the polymer compound solution to form a mixing solution A;
coating the mixing solution A on the anode layer to form a hole injection layer film; and
processing the hole injection layer film at a predetermined temperature by an annealing process.

7. The display panel manufacturing method as claimed in claim 6, wherein the metal oxide is one of ruthenium(IV) oxide, molybdenum oxide, vanadium oxide and tungsten oxide or a combination of at least two of ruthenium(IV) oxide, molybdenum oxide, vanadium oxide and tungsten oxide.

8. The display panel manufacturing method as claimed in claim 6, wherein the polymer compound is one of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK) or a combination of at least two of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole).

9. The display panel manufacturing method as claimed in claim 6, wherein the predetermined temperature of the annealing process is 120° C.

10. A display panel, comprising:
a substrate;
an anode layer formed on the substrate;
an organic light-emitting diode (OLED) layer formed on the anode layer, and the OLED layer comprising a first common layer, a light-emitting layer and a second common layer sequentially stacked over one another, wherein the first common layer comprises particles made of metal oxide; and
a cathode layer formed on the OLED layer.

11. The display panel as claimed in claim 10, wherein the first common layer comprises a polymer compound, and the polymer compound is one of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK) or a combination of at least two of Poly(3,4-ethylenedioxythiophene) (PEDOT), Poly[N,N′-bis(4-butylphenyl)-N,N′-bisphenylbenzidine] (Poly-TPD) and Poly(9-vinylcarbazole) (PVK).

12. The display panel as claimed in claim 10, wherein the first common layer comprises a hole injection layer and a hole transport layer, and the first common layer is configured for hole injection and transport; and
the second common layer comprises an electron injection layer and an electron transport layer, and the second common layer is configured for electron injection and transport.

13. The display panel as claimed in claim 12, wherein the hole injection layer comprises particles made of metal oxide.

14. The display panel as claimed in claim 12, wherein a thickness of the hole injection layer is 10-50 nm.
